(19) United States
(12) Patent Application Publication
(10) Pub. No.: US 2022/0209311 A1
(43) Pub. Date: Jun. 30, 2022

(54) ELECTROCHEMICAL CELL SAFETY DIAGNOSTICS

(71) Applicant: Medtronic, Inc., Minneapolis, MN (US)

(72) Inventors: Hui Ye, Maple Grove, MN (US); Mark E. Viste, Elk River, MN (US); Gang Ji, Medina, MN (US); Gordon O. Munns, Stacy, MN (US); Gaurav Jain, Edina, MN (US); Laura E. McCalla, Brossard (CA)

(21) Appl. No.: 17/528,351

(22) Filed: Nov. 17, 2021

Related U.S. Application Data
(60) Provisional application No. 63/131,068, filed on Dec. 28, 2020.

(51) Int. Cl. H01M 10/42; G01R 31/367; G01R 31/3842; H01M 10/44; G01R 31/387

(52) U.S. Cl. CPC H01M 10/4285; G01R 31/367; G01R 31/387; H01M 10/44; G01R 31/3842

(57) ABSTRACT

At least one electrochemical cell is charged to a predetermined voltage of the electrochemical cell using an external power source. A charging current of the at least one electrochemical cell is monitored. An increase in the charging current is detected at the predetermined voltage of the at least one electrochemical cell. It is determined that the at least one electrochemical cell is in danger of experiencing a performance decrease based on the detected increase in the charging current.

### RELATED APPLICATIONS

This application claims the benefit of U.S. Provisional Patent Application Ser. No. 63/131,068, filed on Dec. 28, 2020, which is incorporated by reference herein in its entirety.

### FIELD

The present disclosure relates to, among other things, electrochemical cells; and particularly to safety diagnostics of electrochemical cells.

### TECHNICAL BACKGROUND

Electrochemical cells can be used in a variety of medical equipment such as ventilators, surgical staplers, medical monitoring equipment, etc. Some electrochemical cells can be recharged to allow repeated use of the electrochemical cells and extend the useful life of such electrochemical cells. However, over time and with repeated use, the electrochemical cells may degrade without showing any outward signs of degradation.

Consequently, some electrochemical cells can fail suddenly and without warning. Failure may include electrochemical cell rupture or electrochemical cell venting. Such failure could damage medical equipment and/or leave the medical equipment without a source of power. However, early detection of electrochemical cell degradation or state of health detection may allow electrochemical cells to be replaced before experiencing failure.

### SUMMARY

Embodiments described herein involve a method comprising charging at least one electrochemical cell to a predetermined voltage of the electrochemical cell using an external power source. A charging current of the at least one electrochemical cell is monitored. An increase in the charging current is detected at the predetermined voltage of the at least one electrochemical cell. It is determined that at least one electrochemical cell is in danger of experiencing a performance decrease based on the detected increase in the charging current.

A system involves an external power source configured to charge at least one electrochemical cell to a predetermined voltage of the electrochemical cell. A controller is configured to cause the external power source to charge the at least one electrochemical cell to a predetermined voltage of the electrochemical cell. A charging current of the electrochemical cell is monitored. An increase in the charging current is detected at the predetermined voltage of the at least one electrochemical cell. It is determined that at least one electrochemical cell is in danger of experiencing a performance decrease based on the detected increase in the charging current.

A method involves charging at least one electrochemical cell to a predetermined voltage of the electrochemical cell using an external power source. A charging current of the at least one electrochemical cell is monitored. An increase in the charging current is detected at the predetermined voltage of at least one electrochemical cell. It is determined whether the increase in the charging current is greater than a predetermined threshold. It is determined that at least one electrochemical cell is in danger of experiencing a performance decrease based the determination that the charging current is greater than the predetermined threshold.

Advantages and additional features of the subject matter of the present disclosure will be set forth in the detailed description which follows, and in part will be readily apparent to those skilled in the art from that description or recognized by practicing the subject matter of the present disclosure as described herein, including the detailed description which follows, the claims, as well as the appended drawings.

It is to be understood that both the foregoing general description and the following detailed description present embodiments of the subject matter of the present disclosure, and are intended to provide an overview or framework for understanding the nature and character of the subject matter of the present disclosure as it is claimed. The accompanying drawings are included to provide a further understanding of the subject matter of the present disclosure and are incorporated into and constitute a part of this specification. The drawings illustrate various embodiments of the subject matter of the present disclosure and together with the description serve to explain the principles and operations of the subject matter of the present disclosure. Additionally, the drawings and descriptions are meant to be merely illustrative and are not intended to limit the scope of the claims in any manner.

### BRIEF DESCRIPTION OF THE DRAWINGS

The following detailed description of specific embodiments of the present disclosure can be best understood when read in conjunction with the following drawings, in which:

FIG. 1 is a schematic block diagram of an embodiment of an electrochemical cell charging apparatus and a device in accordance with embodiments described herein;

FIG. 2 is a schematic block diagram of an embodiment of an electrochemical cell charging apparatus in accordance with embodiments described herein;

FIG. 3 shows a flow diagram to detect potential battery pack failure in accordance with embodiments describe herein;

FIG. 4 illustrates the charging current versus time for multiple charge cycles in accordance with embodiments described herein;

FIG. 5A shows an example of recovered capacity versus time for batteries kept at 37° C., 50° C., and 60° C. in accordance with embodiments described herein;

FIG. 5B shows an example of recoverable capacity versus time for batteries kept at 37° C., 50° C., and 60° C. in accordance with embodiments described herein;

FIGS. 6A and 6B show the charging current versus time for a first battery set and a replacement battery set stored at 60° C. in accordance with embodiments described herein;

FIGS. 7A and 7B show the charging current versus time for a first battery set and a replacement battery set stored at 50° C. in accordance with embodiments described herein;

FIGS. 8A and 8B show the charging current versus time for a first battery set and a replacement battery set stored at 37° C. in accordance with embodiments described herein;

The figures are not necessarily to scale unless otherwise indicated. Like numbers used in the figures refer to like components. However, it will be understood that the use of a number to refer to a component in a given figure is not intended to limit the component in another figure labeled with the same number.

### DETAILED DESCRIPTION

Reference will now be made in greater detail to various embodiments of the subject matter of the present disclosure, some embodiments of which are illustrated in the accompanying drawings. Like numbers used in the figures refer to like components and steps. However, it will be understood that the use of a number to refer to a component in a given figure is not intended to limit the component in another figure labeled with the same number. In addition, the use of different numbers to refer to components in different figures is not intended to indicate that the different numbered components cannot be the same or similar to other numbered components.

Rechargeable battery or battery pack failures can occur when cells are held at the top of charge over an extended period of time, at elevated temperatures, due to internal chemistry or battery chemistry degradation. There is a need for us to detect impending failures early and to take preventative actions. For example, preventative actions may include stopping the charging, sending alerts, declaring the pack as failed, opening FETs, and/or blowing the fuse.

Embodiments described herein involve a method for detecting battery pack failures. Float charge testing for commercial lithium ion cells has shown that before there is pressure rise in the cell that leads to failures (vent blown or current-interrupt device (CID) opening), there is a steady increase in the current to hold the battery pack at a predetermined voltage. For example, the predetermined voltage may be the top of charge for the battery pack. In some cases, the increase in current may be detected at a time when the battery pack is not held at the predetermined voltage. This is in contrast to a normal charging situation where current continues to decline with time. By monitoring the current and setting safe thresholds for this current, a diagnostic can be implemented to detect impending failures.

Current BMS systems have thresholds for various parameters such as over-current, over-voltage, over-temperature, total charge passed, cell imbalance, etc. However, current systems do not have such a diagnostic feature that trends the current in the constant-voltage charge mode with time or with charge cycle number as an indicator of degradation and increased risk of failure.

Embodiments described herein involve electrochemical cell charging apparatuses configured to predict a failure of the electrochemical cell. If a failure is predicted, various system may take various failure mitigation actions before failure of the electrochemical cell.

It has been determined that some electrochemical cells may present an increase in charging current at the top of a charge prior to failure. The electrochemical cell charging apparatus may monitor or determine charging current or a property associated with charging current. For example, the charging apparatus may monitor or determine temperature, pressure, capacitance loss, frequency of recharge, etc. and may determine potential impending failure on the monitored or determined charging current or property associated with charging current.

Some examples of detecting or monitoring of current or a property associated with current include, but are not limited to, detecting current at top of charge; monitoring the frequency of recharge the electrochemical cell while the electrochemical is operatively coupled to the charger; temperature at the top of charge (or period of static float); and the like.

Some charging algorithms for rechargeable electrochemical cells and battery packs include a “recharge state.” in such charging algorithms, the electrochemical cell is charged to a maximum capacity (e.g., 100% state of charge (SOC)) and then charging is ceased. While the charging is ceased, the electrochemical cell may power the charging apparatus, causing the battery to discharge over time. Once the battery drops to a threshold SOC, charging of the electrochemical cell may be enabled to charge the battery back to 100% SOC. This cycle may be repeated until the electrochemical cell is removed from the charger.

A reduction in the ability of an electrochemical cell to remain at a maximum capacity and/or other predetermined voltage may be an early indicator of electrochemical cell damage. Such loss of capacity may be caused by internal shorts resulting from separator damage, foreign material conduction, or other factors related to the inability of the electrochemical cell to maintain full charge. Detection of a loss of charge can be performed during charging periods where the electrochemical cell charge level normally would be expected to be static.

A damaged electrochemical cell may not be able to maintain its charge level when a charging current is removed. A voltage of a damaged electrochemical cell may droop during a static charger “float” time period. Such drooping voltage is indicative of a current leak and a loss in electrochemical cell capacity. Additionally or alternatively, a damaged electrochemical cell may experience a rise in charging current when the expected charging current is less than a predetermined value (e.g., 1 mA), for example. Such charging currents can be greater than or equal to 1 mA when the expected charging current is less than 1 mA.

The apparatus, systems, and methods described herein may enhance the performance and reliability of electrochemical cells or battery packs. Shutting down or replacing the electrochemical cell or the battery pack early enough may prevent build-up of internal electrochemical cell pressure that may otherwise reach levels that would cause electrochemical cell to rupture or cause electrochemical cell electrolyte venting.

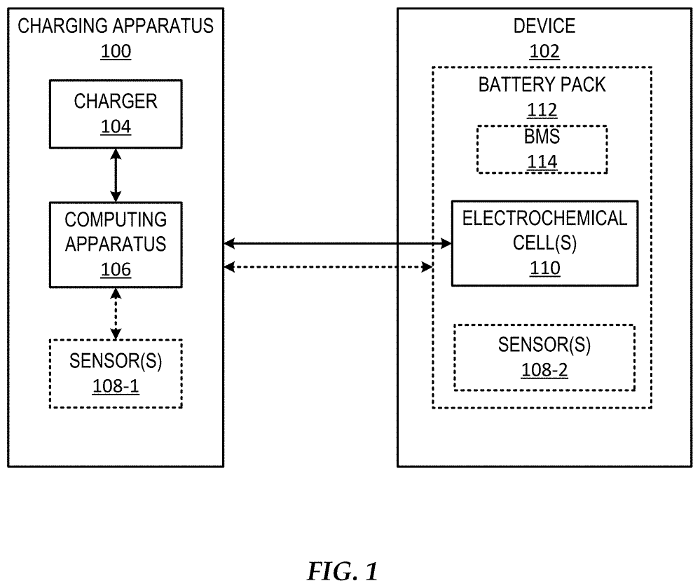

Referring now to FIG. 1, a schematic block diagram of a charging apparatus 100 and a device 102 is shown.

The charging apparatus 100 includes a charger 104 and a computing apparatus 106. The charging apparatus 100 may optionally include one or more sensors 108-1. The charger 100 may include a housing (not shown) to house the charger 104 and the computing apparatus 106. The housing may also house the sensors 108-1.

The device 102 includes one or more electrochemical cells 110. The electrochemical cells 110 can optionally be included in a battery pack 112. The battery pack 112 may include a battery management system (BMS) 114 and one or more sensors 108-2. The device 102 may be a medical device. The medical device may be a ventilator, surgical stapler, or medical monitoring equipment, for example.

The charger 104 may be configured to charge the electrochemical cells 110 or battery pack 112. The charger 104 may include any suitable circuitry or electronics to charge the electrochemical cells 110 or battery pack 112 such as, e.g., a power source, rectifier circuit, power circuit, control circuit, regulator circuit, fault detection circuit, etc.

The computing apparatus 104 may be operatively coupled to the charger 104. The computing apparatus 104 may control the charger to charge the electrochemical cells 110. The computing apparatus 104 may be operatively coupled to the sensors 108-1. The computing apparatus may be configured to monitor various conditions related to charging the electrochemical cells 110 such as, e.g., charging current, voltage, temperature, etc. Additionally, the computing apparatus 106 may be configured to determine a state of health of the electrochemical cells 110 according to the various methods described herein. For example, the computing apparatus 106 may be configured to determine the potential failure of the electrochemical cells 110 based on a charging current, electrochemical cell temperature, temperature difference, recharge frequency, capacitance fade, etc. Furthermore, the computing apparatus 106 may be configured to determine charging current, electrochemical cell temperature, temperature difference, recharge frequency, or capacitance fade based on the monitored conditions related to charging the electrochemical cells 110.

The electrochemical cells 110 may include any suitable type or chemistry such as, e.g., nickel metal hydride, lithium ion, lead acid, etc. The electrochemical cells 110 are rechargeable electrochemical cells. The electrochemical cells 110 may have any suitable voltage, capacity, supply current, etc. The electrochemical cells 110 may be incorporated into a battery pack 112.

The battery pack 112 may include a plurality of electrochemical cells 110. The electrochemical cells 110 can be arranged in parallel, series, or a combination thereof. The battery pack 112 may include the BMS 114 to monitor the electrochemical cells 110, maintain safe operating conditions of the electrochemical cells, reporting various conditions of the electrochemical cells, etc. The battery pack 112 may further include sensors 108-2 to sense temperature, voltage, current, etc.

The sensors 108-1, 108-2 (referred to collectively as sensors 108) may include any suitable sensor or sensors such as, e.g., temperature sensors, current sensors, voltage sensors, state of charge sensors, etc. The sensors 108 may provide a sensed temperature signal, sensed current signal, sensed voltage signal, sensed state of charge signal, etc. The signals provided by the sensors 108 may be indicative of the properties sensed by the sensors.

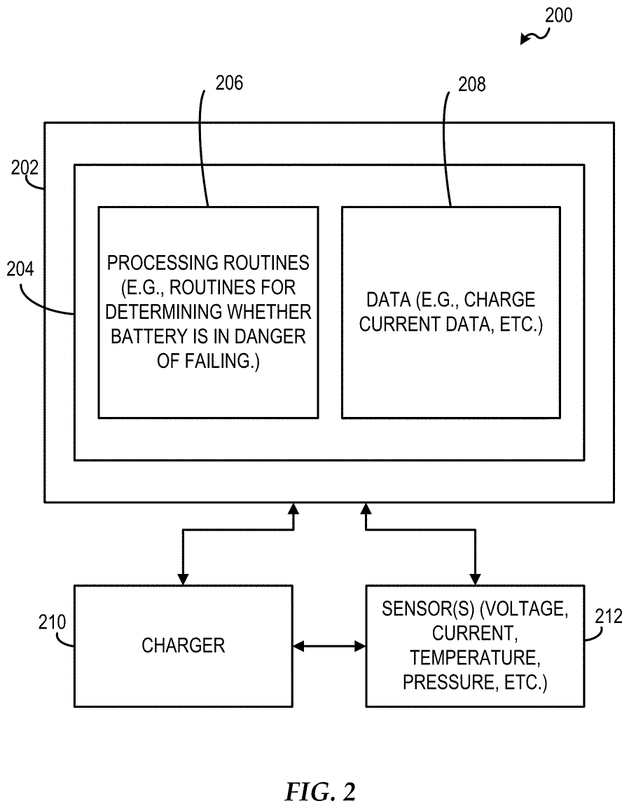

Referring now to FIG. 2, a schematic block diagram of a charging apparatus 200 according to embodiments described herein is shown. The charging apparatus 200 may include a computing apparatus or processor 202 and a charger 210. Generally, the charger 210 may be operably coupled to the computing apparatus 202 and may include any suitable circuits or devices configured charge electrochemical cells. For example, the charger 210 may include one or more power sources, rectifier circuits, power circuits, control circuits, regulator circuits, fault detection circuits, etc.

The charging apparatus 200 may additionally include one or more sensors 212 operably coupled to the computing apparatus 202. Generally, the sensors 212 may include any one or more devices configured to sense charging information of the charger 210 or electrochemical cells. The sensors 212 may include any apparatus, structure, or device to capture the charging information of the charger such as one or more current sensors, voltage sensors, temperature sensors, etc.

Further, the computing apparatus 202 includes data storage 204. Data storage 204 allows for access to processing programs or routines 206 and one or more other types of data 208 that may be employed to carry out the techniques, processes, and algorithms of determining whether an electrochemical cell is in danger experiencing a performance decrease. For example, processing programs or routines 206 may include programs or routines for determining a charging current, determining a temperature difference, determining a frequency of recharge, determining a state of health of an electrochemical cell, computational mathematics, matrix mathematics, Fourier transforms, compression algorithms, calibration algorithms, image construction algorithms, inversion algorithms, signal processing algorithms, normalizing algorithms, deconvolution algorithms, averaging algorithms, standardization algorithms, comparison algorithms, vector mathematics, analyzing sound data, analyzing hearing device settings, detecting defects, or any other processing required to implement one or more embodiments as described herein.

Data 208 may include, for example, temperature data, voltage data, charging current data, state of health data, state of charge data, thresholds, arrays, meshes, grids, variables, counters, statistical estimations of accuracy of results, results from one or more processing programs or routines employed according to the disclosure herein (e.g., determining a state of health of an electrochemical cell, etc.), or any other data that may be necessary for carrying out the one or more processes or techniques described herein.

In one or more embodiments, the charging apparatus 200 may be controlled using one or more computer programs executed on programmable computers, such as computers that include, for example, processing capabilities (e.g., microcontrollers, programmable logic devices, etc.), data storage (e.g., volatile or non-volatile memory and/or storage elements), input devices, and output devices. Program code and/or logic described herein may be applied to input data to perform functionality described herein and generate desired output information. The output information may be applied as input to one or more other devices and/or processes as described herein or as would be applied in a known fashion.

The programs used to implement the processes described herein may be provided using any programmable language, e.g., a high-level procedural and/or object orientated programming language that is suitable for communicating with a computer system. Any such programs may, for example, be stored on any suitable device, e.g., a storage media, readable by a general or special purpose program, computer or a processor apparatus for configuring and operating the computer when the suitable device is read for performing the procedures described herein. In other words, at least in one embodiment, the charging apparatus 200 may be controlled using a computer readable storage medium, configured with a computer program, where the storage medium so configured causes the computer to operate in a specific and predefined manner to perform functions described herein.

The computing apparatus 202 may be, for example, any fixed or mobile computer system (e.g., a personal computer or minicomputer). The exact configuration of the computing apparatus is not limiting and essentially any device capable of providing suitable computing capabilities and control capabilities (e.g., control the sound output of the charging apparatus 200, the acquisition of data, such as image data, audio data, or sensor data) may be used. Additionally, the computing apparatus 202 may be incorporated in a housing of the charging apparatus 200. Further, various peripheral devices, such as a computer display, mouse, keyboard, memory, printer, scanner, etc. are contemplated to be used in combination with the computing apparatus 202. Further, in one or more embodiments, the data 208 (e.g., image data, sound data, voice data, audio classes, audio objects, optical components, hearing impairment settings, hearing device settings, an array, a mesh, a digital file, etc.) may be analyzed by a user, used by another machine that provides output based thereon, etc. As described herein, a digital file may be any medium (e.g., volatile or non-volatile memory, a CD-ROM, a punch card, magnetic recordable tape, etc.) containing digital bits (e.g., encoded in binary, trinary, etc.) that may be readable and/or writeable by computing apparatus 202 described herein. Also, as described herein, a file in user-readable format may be any representation of data (e.g., ASCII text, binary numbers, hexadecimal numbers, decimal numbers, audio, graphical) presentable on any medium (e.g., paper, a display, sound waves, etc.) readable and/or understandable by a user.

In view of the above, it will be readily apparent that the functionality as described in one or more embodiments according to the present disclosure may be implemented in any manner as would be known to one skilled in the art. As such, the computer language, the computer system, or any other software/hardware that is to be used to implement the processes described herein shall not be limiting on the scope of the systems, processes or programs (e.g., the functionality provided by such systems, processes or programs) described herein.

The techniques described in this disclosure, including those attributed to the systems, or various constituent components, may be implemented, at least in part, in hardware, software, firmware, or any combination thereof. For example, various aspects of the techniques may be implemented by the computing apparatus 202, which may use one or more processors such as, e.g., one or more microprocessors, DSPs, ASICs, FPGAs, CPLDs, microcontrollers, or any other equivalent integrated or discrete logic circuitry, as well as any combinations of such components, image processing devices, or other devices. The term “processing apparatus,” “processor,” or “processing circuitry” may generally refer to any of the foregoing logic circuitry, alone or in combination with other logic circuitry, or any other equivalent circuitry. Additionally, the use of the word “processor” may not be limited to the use of a single processor but is intended to connote that at least one processor may be used to perform the techniques and processes described herein.

Such hardware, software, and/or firmware may be implemented within the same device or within separate devices to support the various operations and functions described in this disclosure. In addition, any of the described components may be implemented together or separately as discrete but interoperable logic devices. Depiction of different features, e.g., using block diagrams, etc., is intended to highlight different functional aspects and does not necessarily imply that such features must be realized by separate hardware or software components. Rather, functionality may be performed by separate hardware or software components or integrated within common or separate hardware or software components.

When implemented in software, the functionality ascribed to the systems, devices and techniques described in this disclosure may be embodied as instructions on a computer-readable medium such as RAM, ROM, NVRAM, EEPROM, FLASH memory, magnetic data storage media, optical data storage media, or the like. The instructions may be executed by the computing apparatus 202 to support one or more aspects of the functionality described in this disclosure.

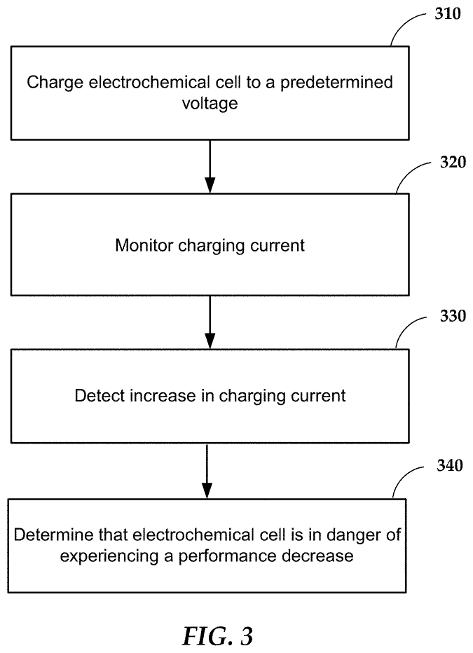

Referring now to FIG. 3, a method to determine if an electrochemical cell has and/or may experience a performance decrease in accordance with embodiments describe herein is shown. According to various configurations, the performance decrease may be indicative that the at least one electrochemical cell is in danger of failing. At least one electrochemical cell is charged to a predetermined voltage using an external power source. A charging current of the at least one electrochemical cell is monitored 320. The charging current may be monitored while the electrochemical cell is charging and/or during a period of static float between charge cycles.

An increase in the charging current while the electrochemical cell is held at the predetermined voltage of the at least one electrochemical cell may be detected 330 based on the monitoring 320. According to various configurations, the predetermined voltage is substantially the maximum capacity of the at least one electrochemical cell. According to various implementations, detecting an increase in the charging current comprises determining a rate of increase of the charging current. Some embodiments involve determining a rate of increase of the charging current over more than one charging cycle.

It is determined 340 that the at least one electrochemical cell is in danger of experiencing a performance decrease based on the detected increase in the charging current. According to various embodiments described herein, it is determined whether the increase in the charging current is greater than a predetermined threshold. It is determined 340 that the at least one electrochemical cell is in danger of experiencing a performance decrease based on the determination that the increase in the charging current is greater than the predetermined threshold. In some cases, the predetermined threshold is a rate of current increase.

According to various configurations, the detected charging current may be compared to a respective charging current of other cells within the battery pack and/or other battery packs in similar conditions. For example, an electrochemical cell may be compared to one or more neighboring electrochemical cells in a battery pack. The comparison may be used to determine if there is a decrease in performance of the one or more electrochemical cells.

According to some embodiments, one or more failure mitigation actions are taken based on a determination that electrochemical cell failure is likely to occur. For example, the failure mitigation actions may include stopping the charging of the electrochemical cell, sending one or more alerts, opening one or more field effect transistors (FETs) (e.g., charging FETs) of the electrochemical cell, and/or blowing one or more fuses of the electrochemical cell. The alerts may include one or more of audible alerts, visual alerts, and/or tactile alerts. For example, an alert apparatus may be used such as a speaker, a vibrator, and/or a display.

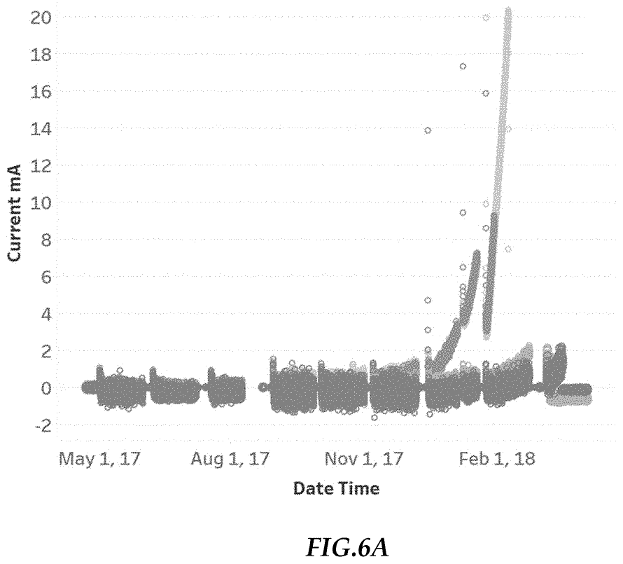

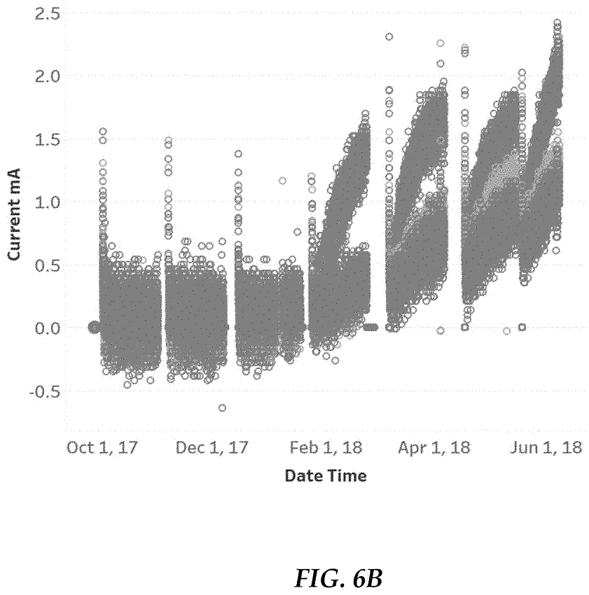

The BMS may choose the one or more failure mitigation actions based on the detected rate of current increase. A series of thresholds may be used to determine an appropriate action. The thresholds may depend on an estimated time to failure based on the rate of current increase. For example, if the rate is above a first threshold and below a second threshold, the BMS may stop charging the electrochemical cell and/or send one or more alerts. If the rate is above the second threshold, the BMS may open the FETs and/or blow the one or more fuses. According to various configurations, the various thresholds described herein may depend on operating voltage and/or temperature. For example, in FIG. 6A, in one month two cells have a slight uptick at the end of the month in November. In the next month, the slope picks up. In the following month, the slope really picks up. For these cells, a 2 mA threshold would have given more than a month's warning. The timing of the progression and the magnitude of the threshold will depend on (at least) hold voltage, temperature, and/or the cell type

According to various embodiments, when the batteries are held in a fully charged state, they will be charged to 100% and then allowed to discharge to a predetermined percentage. For example, the batteries may be allowed to discharge to about 93% and then charged back to full again. The cycle then continues until the battery is removed from the charger. If a battery failure is determined to be likely, the one or more FETs are opened for a predetermined period of time, e.g., 10 hours. This causes the battery to miss the 93% recharge and the battery may be allowed to discharge during this time. For example, the cells may be discharged to about 35% before being allowed to charge again. In this example, a discharge rate in a range of about 110 mA to about 120 mA causes a 65% reduction in charge in about 10 hours. According to various configurations, the rate of timing of the discharge may be used to monitor parasitic leakage, which can give rise to CID opening.

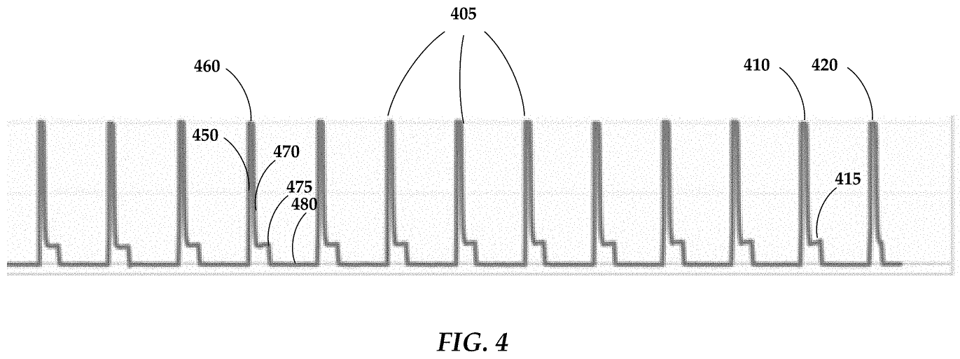

FIG. 4 illustrates the charging current versus time for multiple charge cycles 405 in accordance with embodiments described herein. Each charge cycle has several portions. A charging portion 450 is shown at the beginning of the charging cycle. The charging current increases until the battery is substantially charged 460. The charge cycle then enters the float portion and the charging current drops 470. The charging current may drop exponentially until a minimum charging current 480. According to various embodiments, the charging current plateaus 475 at about 100 mA before dropping to a minimum charging current 480.

According to various implementations, the plateauing of the charging current may be indicative of impending battery failure. The first two charge cycles of FIG. 4 show substantially healthy charge cycles. The charging current remains at the minimum charging current until the next charge cycle begins. The timing of the charge cycles may be based on a time between the beginning and/or end of a previous charge cycle. For example, the float portion of the charging cycle may be about 3.5 hours. In some cases, the timing of the charge cycles depends on the state of charge of the battery. For example, the float portion may last until the battery discharges to about 93% of the total charge capacity. In the example shown in FIG. 4, a battery pack failure occurs in the last charge cycle 420. As can be observed, in the charge cycle directly prior to the failure 410, the charging current increases 415 instead of plateauing as shown in previous charge cycles.

According to various embodiments backup battery packs may be kept at high voltage. In some cases, the backup battery packs are kept at relatively high temperature. For example, the battery packs may be stored at a temperature in a range of about 37° C. to about 60° C. The repeated charge cycles and/or the high heat may cause the battery health to degrade over time. A decrease in battery health may involve a decrease in battery capacity and/or a decrease in performance.

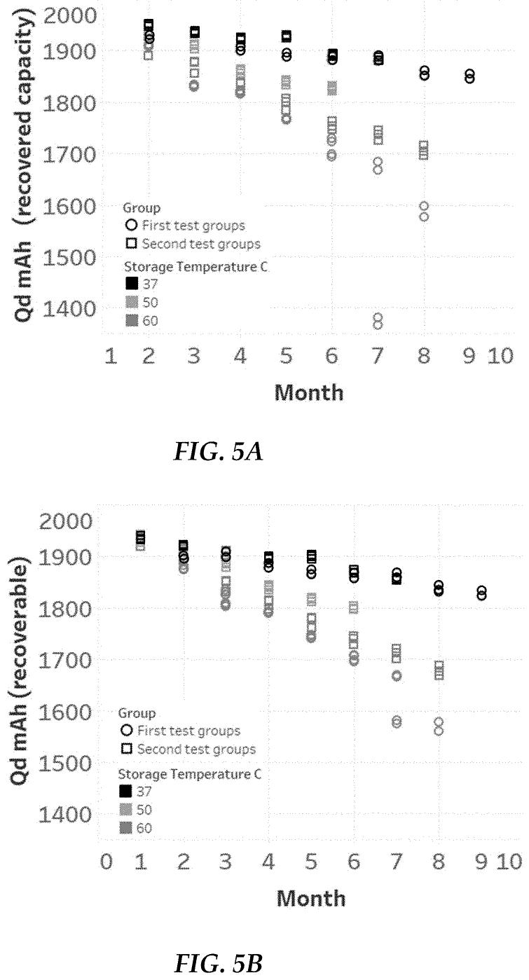

FIG. 5A shows an example of recovered capacity (about one month after storage) versus time for batteries kept at 37° C., 50° C., and 60° C. Similarly, FIG. 5B shows an example of recoverable capacity (about three months after storage) versus time for batteries kept at 37° C., 50° C., and 60° C. As can be observed, the batteries stored at the higher temperatures had more of a drop in capacity than the batteries stored at the relatively lower temperatures. Observing both the recovered and recoverable capacity may be useful to determine whether degradation of the cells is permanent. For the type of cells shown in FIGS. 5A and 5B, the difference between the recovered and recoverable capacity is fairly subtle. For other types of cells and/or at different conditions, the differences between the recovered and the recoverable capacity may be more pronounced.

FIGS. 6A and 6B show the charging current versus time for a first battery set and a replacement battery set, respectively. In this example, both the first battery set and the second battery set were stored at about 60° C. As can be observed, both battery sets experienced an increase in the charging current. In the first set shown in FIG. 6A, the charging current started increasing in about December 2017. In the replacement set shown in FIG. 6B, the charging current started increasing in about February 2018.

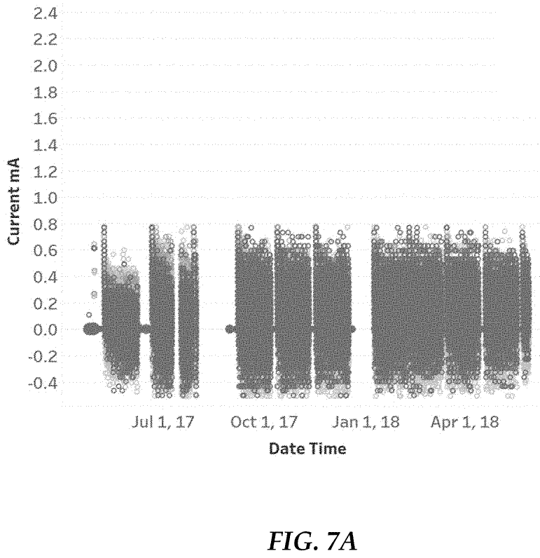

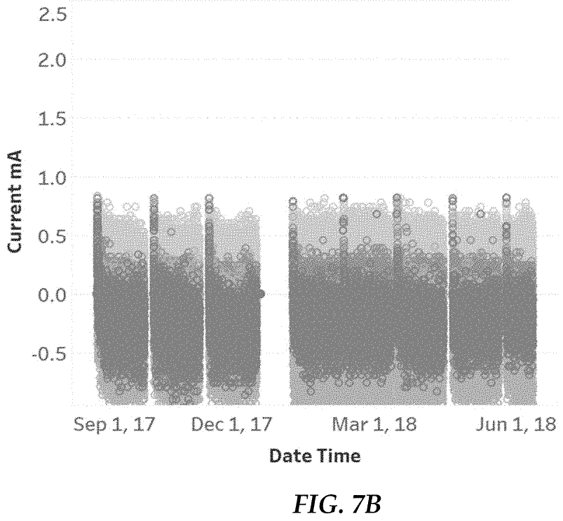

FIGS. 7A and 7B show the charging current versus time for a first battery set and a replacement battery set, respectively. In this example, both the first battery set and the second battery set were stored at about 50° C. As can be observed, neither battery set experienced an increase in the charging current.

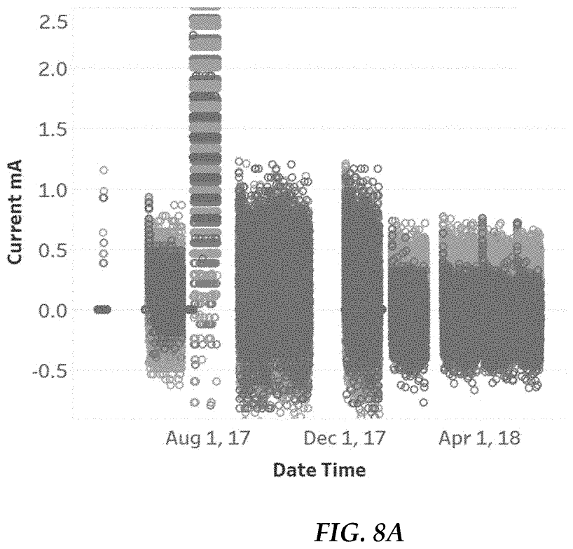

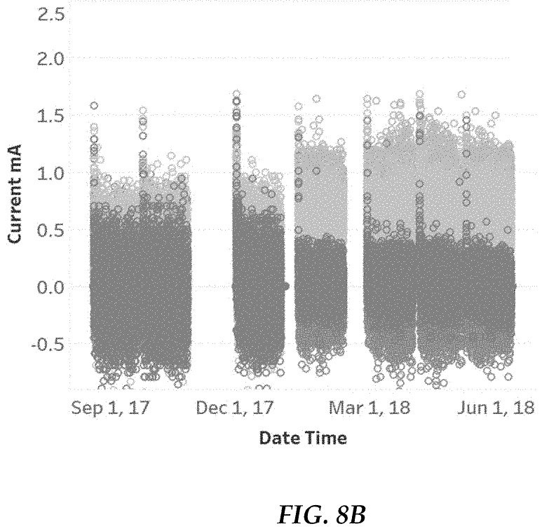

FIGS. 8A and 8B show the charging current versus time for a first battery set and a replacement battery set, respectively. In this example, both the first battery set and the second battery set were stored at about 37° C. As can be observed, neither battery set experienced an increase in the charging current.

All scientific and technical terms used herein have meanings commonly used in the art unless otherwise specified. The definitions provided herein are to facilitate understanding of certain terms used frequently herein and are not meant to limit the scope of the present disclosure.

As used herein, singular forms “a,” “an” and “the” include plural referents unless the context clearly dictates otherwise. As used in this specification and the appended claims, the term “or” is generally employed in its sense including “and/or” unless the content clearly dictates otherwise. The term “and/or” means one or all of the listed elements or a combination of any two or more of the listed elements.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the inventive technology.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred. Any recited single or multiple feature or aspect in any one claim can be combined or permuted with any other recited feature or aspect in any other claim or claims.

It will be apparent to those skilled in the art that various modifications and variations can be made to the present inventive technology without departing from the spirit and scope of the disclosure. Since modifications, combinations, sub-combinations and variations of the disclosed embodiments incorporating the spirit and substance of the inventive technology may occur to persons skilled in the art, the inventive technology should be construed to include everything within the scope of the appended claims and their equivalents.

What is claimed is:

1. A method, comprising:
charging at least one electrochemical cell to a predetermined voltage of the electrochemical cell using an external power source;
monitoring a charging current of the at least one electrochemical cell;
detecting an increase in the charging current at the predetermined voltage of the at least one electrochemical cell; and
determining that the at least one electrochemical cell is in danger of experiencing a performance decrease based on the detected increase in the charging current.

2. The method of claim 1, wherein detecting an increase in the charging current comprises determining a rate of increase of the charging current.

3. The method of claim 2, wherein the rate of increase of the charging current comprises the rate of increase of the charging current over a predetermined number of charging cycles.

4. The method of claim 1, further comprising determining whether the increase in the charging current is greater than a predetermined threshold and wherein determining that the at least one electrochemical cell is in danger of experiencing a performance decrease based on the determination that the increase in the charging current is greater than the predetermined threshold.

5. The method of claim 1, further comprising initiating at least one failure mitigation action of a plurality of failure mitigation actions based on the determination that the at least one electrochemical cell is in danger of experiencing a performance decrease.

6. The method of claim 5, wherein the plurality of failure mitigation actions comprise:
stopping the charging of the at least one electrochemical cell;
sending one or more alerts;
opening one or more field effect transistors (FETs) associated with the at least one electrochemical cell; and
blowing one or more fuses associated with the at least one electrochemical cell.

7. The method of claim 6, further comprising determining which of the plurality of failure mitigation actions to take based on a rate of increase of the charging current.

8. A system, comprising:
an external power source configured to charge at least one electrochemical cell to a predetermined voltage of the electrochemical cell;
a controller configured to:
cause the external power source to charge the at least one electrochemical cell to a predetermined voltage of the electrochemical cell;
monitor a charging current of the electrochemical cell;
detect an increase in the charging current at the predetermined voltage of the electrochemical cell; and
determine that the electrochemical cell is in danger of experiencing a performance decrease based on the detected increase in the charging current.

9. The system of claim 8, wherein the controller is configured to:
determine a rate of increase of the charging current; and
determine that the electrochemical cell is in danger of experiencing a performance decrease based on the detected rate of increase of the charging current.

10. The system of claim 9, wherein the rate of increase of the charging current comprises the rate of increase of the charging current over a predetermined number of charging cycles.

11. The system of claim 8, wherein the controller is configured to:
determine whether the increase in the charging current is greater than a predetermined threshold; and
determine that the at least one electrochemical cell is in danger of experiencing a performance decrease based on the determination that the increase in the charging current is greater than the predetermined threshold.

12. The system of claim 8, wherein the controller is configured to initiate at least one failure mitigation action of a plurality of failure mitigation actions based on the determination that the at least one electrochemical cell is in danger of experiencing a performance decrease.

13. The system of claim 12, wherein the plurality of failure mitigation actions comprise:
stopping the charging of the at least one electrochemical cell;
sending one or more alerts;
opening one or more field effect transistors (FETs) associated with the at least one electrochemical cell; and
blowing one or more fuses associated with the at least one electrochemical cell.

14. The system of claim 13, wherein the controller is configured to determine which of the plurality of failure mitigation actions to take based on a rate of increase of the charging current.

15. The system of claim 8, wherein the at least one electrochemical cell is disposed in a medical device.

16. The system of claim 8, further comprising a battery pack, wherein the battery pack comprises:
a plurality of electrochemical cells the plurality of electrochemical cells comprising the at least one electrochemical cell; and
a battery management apparatus operatively coupled to the controller comprising one or more sensors to sense one or more of a voltage, a state of charge, a charging current, and a temperature of each of the plurality of electrochemical cells.

17. A method, comprising:
charging at least one electrochemical cell to a predetermined voltage of the electrochemical cell using an external power source;
monitoring a charging current of the at least one electrochemical cell;
detecting an increase in the charging current at the predetermined voltage of the at least one electrochemical cell;
determining whether the increase in the charging current is greater than a predetermined threshold; and
determining that the at least one electrochemical cell is in danger of experiencing a performance decrease based the determination that the charging current is greater than the predetermined threshold.

18. The method of claim 17, wherein detecting an increase in the charging current comprises determining a rate of increase of the charging current.

19. The method of claim 17, further comprising initiating at least one failure mitigation action of a plurality of failure mitigation actions based on the determination that the at least one electrochemical cell is in danger of experiencing a performance decrease.

20. The method of claim 19, wherein the plurality of failure mitigation actions comprise:
stopping the charging of the at least one electrochemical cell;
sending one or more alerts;
opening one or more field effect transistors (FETs) associated with the at least one electrochemical cell; and
blowing one or more fuses associated with the at least one electrochemical cell.
